(19) United States
(12) Patent Application Publication
(10) Pub. No.: US 2009/0061588 A1
(43) Pub. Date: Mar. 5, 2009

(54) METHOD FOR FABRICATING DYNAMIC RANDOM ACCESS MEMORY

(75) Inventors: Chang-Ho Yeh, Taipei City (TW); Hong-Wen Lee, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 11/969,924

(22) Filed: Jan. 7, 2008

(30) Foreign Application Priority Data
Sep. 4, 2007 (TW) 96132882

(51) Int. Cl. H01L 21/8242

(52) U.S. Cl. 438/386; 257/E21.647

(57) ABSTRACT

A method for fabricating a dynamic random access memory is provided. A substrate having two trench capacitors therein is provided, an isolation structure protruding from a surface of the substrate is formed on each trench capacitor, a spacer is formed on the substrate at two sides of each of the isolation structures, and a block layer is formed between each spacer and each isolation structure and between each spacer and the substrate. A trench is formed in the substrate between the trench capacitors, and partial of the trench is located under partial of the spacers and partial of the block layer. The spacers, the block layer, and partial of the isolation structures above the trench are removed. A gate structure protruding from the surface of the substrate is formed in the trench. A doped region is formed in the substrate at each of two sides of the gate structure.

### CROSS-REFERENCE TO RELATED APPLICATION

This application claims the priority benefit of Taiwan application serial no. 96132882, filed on Sep. 4, 2007. The entirety of the above-mentioned patent application is hereby incorporated by reference herein and made a part of this specification.

### BACKGROUND OF THE INVENTION

1. Field of the Invention

The present invention relates to a method for fabricating a memory device. More particularly, the present invention relates to a method for fabricating a dynamic random access memory (DRAM).

2. Description of Related Art

Generally, a memory unit of a DRAM is composed of a transistor together with a capacitor. As the size of a device is increasingly reduced, for a DRAM device having a capacitor, the space available therein for fabricating the capacitor becomes increasingly small. A trench capacitor located in a substrate can effectively use the space in the substrate, so it quite meets with the recent market requirements. Recently, the semiconductor industry can generally fabricate a DRAM having a deep trench (DT) capacitor, which is capable of storing large capacitance and presenting high performance.

In addition, the transistor of the conventional DRAM is a stacking gate structure. As the circuit integration is improved and the device size is reduced, a channel of the transistor is shortened accordingly to result in punch-through phenomenon and short channel effect (SCE). In order to solve the problems of punch-through phenomenon and SCE, usually a recess channel process is used to increase the length of the channel to reduce the punch-through phenomenon and the SCE.

FIGS. 1A to 1B are cross-sectional views of the fabrication flow of a conventional DRAM using a recess channel transistor.

Firstly, referring to FIG. 1A, a substrate 100 is provided. Trench capacitors 102 are formed on the substrate 100, an isolation structure 104 is formed on the trench capacitor 102, the isolation structure 104 protrudes from a surface of the substrate 100, a spacer 106 is formed on the substrate 100 at two sides of the isolation structure 104, and a block layer 108 is formed between the spacers 106 and the isolation structures 104 and between the spacers 106 and the substrate 100. The trench capacitor 102 is located in the substrate 100, and includes a lower electrode 110, a dielectric layer 112, and an upper electrode 114 (composed of a conductor layer 114a, a conductor layer 114b, and a conductor layer 114c). A collar oxide 116 is disposed between the conductor layer 114b and the substrate 100. In addition, an embedded conductive strap 118 electrically connected to the conductor layer 114c is formed in the substrate 100.

Next, an anisotropic etching process is performed on the substrate 100 with the spacers 106 between the trench capacitors 102 as a mask, so as to form a trench 120 in the substrate 100.

Then, referring to FIG. 1B, an isotropic etching process is performed on the substrate 100 in the trench 120, such that point angles of the trench 120 are rounded, the width of the trench 120 becomes wider, so partial of the trench 120 is located under partial of the spacers 106 and partial of the block layer 108.

Next, a dielectric layer 122 and a conductor layer 124 are formed on the surface of the lower portion of the trench 120. Then, a collar oxide 126 is formed on a sidewall of the trench 120 that is not covered by the conductor layer 124. Then, a conductor material layer 128 used to form partial of the gate is formed on the substrate 100.

However, it should be noted that an opening of the trench 120 is limited by the spacers 106 and the block layer 108, so the opening of the trench 120 is smaller than the width of the trench 120. Therefore, when the conductor material layer 128 is filled in the trench 120, a void 130 may be generated in the conductor material layer 128 filled in the trench 120, such that electrical defects occur in the subsequently formed recess channel transistor.

### SUMMARY OF THE INVENTION

Accordingly, the present invention is directed to provide a method for fabricating a DRAM, which is capable of effectively avoid generating voids in a gate structure of a recess channel transistor.

The present invention provides a method for fabricating a DRAM including the following steps. Firstly, a substrate is provided, two trench capacitors are formed in the substrate, and an isolation structure is formed on each trench capacitor, each isolation structure protrudes from a surface of the substrate, a spacer is formed on the substrate at two sides of each isolation structure, and a block layer is formed between each spacer and each isolation structure and between each spacer and the substrate. Next, a trench is formed in the substrate between the trench capacitors by etching with the isolation structures and the spacers as a mask, and partial of the trench is located under partial of the spacers and partial of the block layer. Then, the spacers, the block layer, and partial of the isolation structures above the trench are removed. Then, a gate structure is formed in the trench, and the gate structure protrudes from the surface of the substrate. Next, a doped region is respectively formed in the substrate at each of two sides of the gate structure.

In the method for fabricating a DRAM according to an embodiment of the present invention, the material of the isolation structures includes silicon oxide.

In the method for fabricating a DRAM according to an embodiment of the present invention, the material of the spacers includes silicon oxide.

In the method for fabricating a DRAM according to an embodiment of the present invention, the material of the block layer includes silicon nitride.

In the method for fabricating a DRAM according to an embodiment of the present invention, the method of forming the trench includes performing an anisotropic etching process on the substrate with the spacers between the trench capacitors as a mask, and performing an isotropic etching process on the substrate in the trench.

In the method for fabricating a DRAM according to an embodiment of the present invention, the anisotropic etching process includes a reactive ion etching process.

In the method for fabricating a DRAM according to an embodiment of the present invention, the isotropic etching process includes a chemical dry etching (CDE) process.

In the method for fabricating a DRAM according to an embodiment of the present invention, the method of removing the spacers, the block layer, and partial of the isolation structures above the trench includes a chemical mechanical polishing method.

Based on the above mentioned, in the method for fabricating the DRAM provided by the present invention, the spacers and the block layer above the trench are removed, so as to enlarge the width of the opening of the trench. Therefore, when the gate structure is subsequently formed in the trench, the trench filling capability of the conductor material filling into the trench is enhanced, so as to avoid generating voids in the formed gate structure, thereby improving the electrical performance of the transistor.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1B are cross-sectional views of the fabrication flow of a conventional DRAM using a recess channel transistor.

FIGS. 2A-2D are cross-sectional views of the fabrication flow of a DRAM according to an embodiment of the present invention.

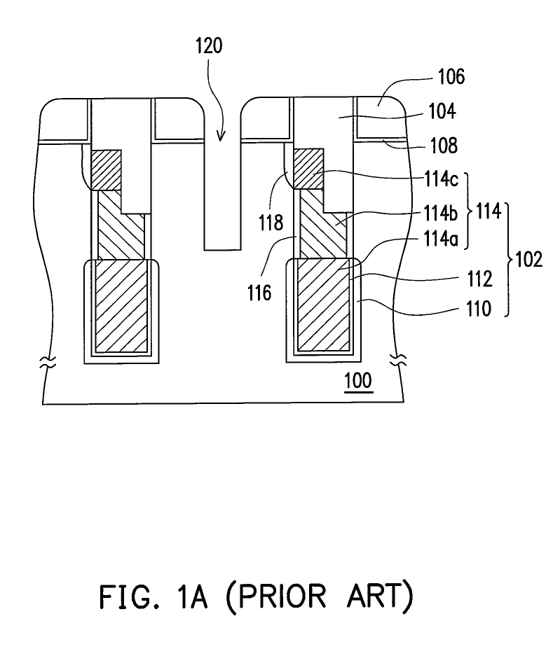

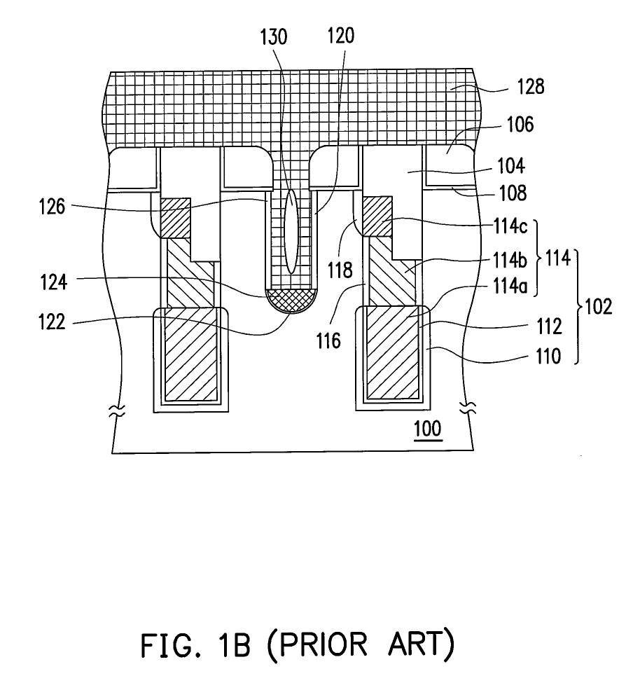

### DESCRIPTION OF EMBODIMENTS

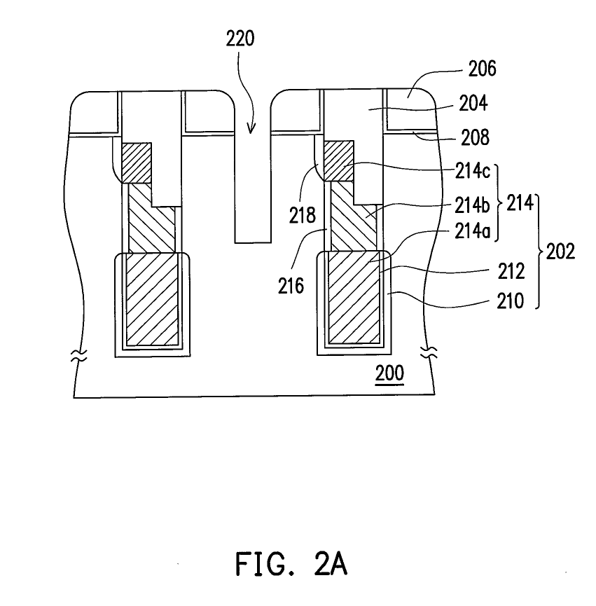

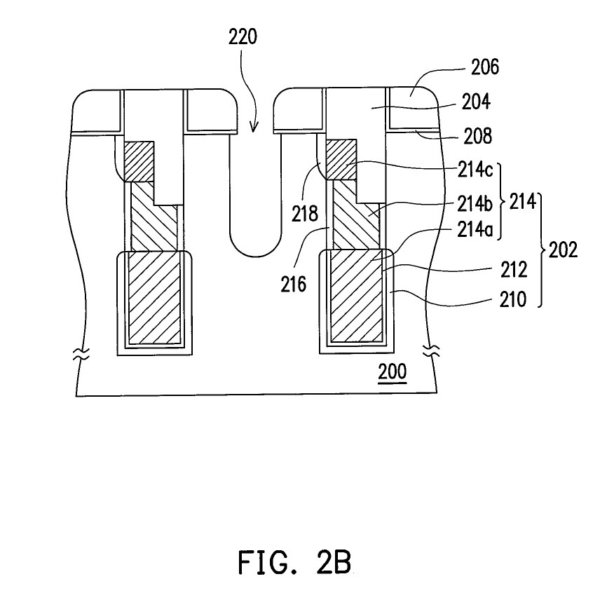

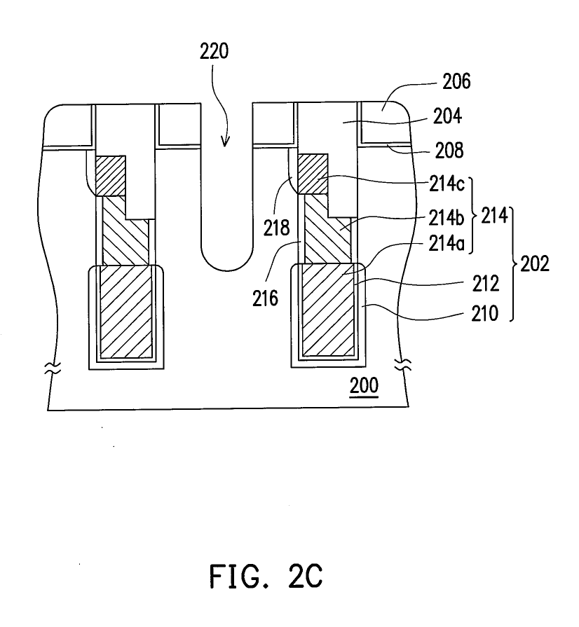

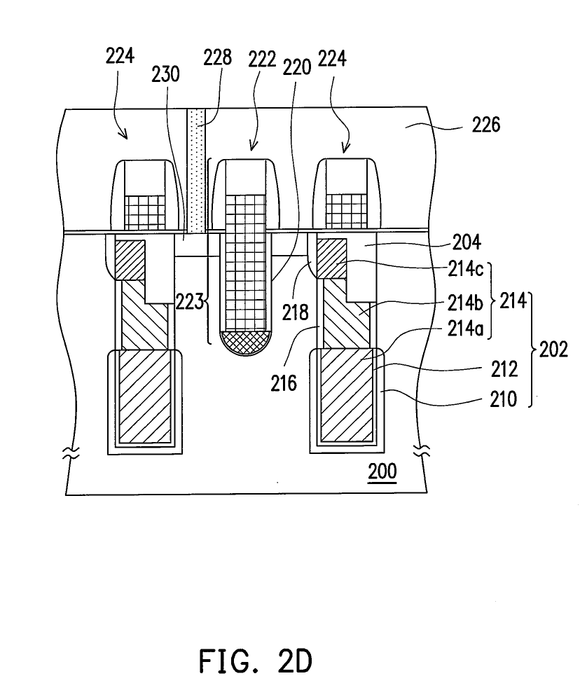

FIGS. 2A-2D are cross-sectional views of the fabrication flow of a DRAM according to an embodiment of the present invention.

Firstly, referring to FIG. 2A, a substrate 200 is provided. Trench capacitors 202 are formed in the substrate 200, and an isolation structure 204 is formed on a top of the trench capacitor 202. The isolation structure 204 protrudes from a surface of the substrate 200, a spacer 206 is formed on the substrate 200 at two sides of the isolation structure 204, and a block layer 208 is formed between the spacers 206 and the isolation structures 204, and between the spacers 206 and the substrate 200. The material of the isolation structures 204 and the spacers 206 is, for example, silicon oxide, and the material of the block layer 208 is for, example, silicon nitride. The trench capacitor 202 is located in the substrate 200, and includes a lower electrode 210, a dielectric layer 212, and an upper electrode 214 (composed of a conductor layer 214a, a conductor layer 214b, and a conductor layer 214c). A collar oxide 216 is disposed between the conductor layer 214b and the substrate 200. In addition, an embedded conductive strap 218 electrically connected to the conductor layer 214c is formed in the substrate 200. The methods of forming the trench capacitors 202, the isolation structures 204, the spacers 206, the block layer 208, and the embedded conductive strap 218 are well known by those of ordinary skill in the technical field, so they are not described here.

Next, an anisotropic etching is performed on the substrate 200.In the etching process, the isolation structures 204 and the spacers 206 are used as hard masks. The anisotropic etching process performed on the substrate 200 is, for example, a reactive ion etching process.

Then, referring to FIG. 2B, an isotropic etching process is then performed in the trench 220, such that point angles of the trench 220 are rounded, the width of the trench 220 becomes wider, so partial of the trench 220 is located under partial of the spacers 206 and partial of the block layer 208. The isotropic etching process performed on the substrate 200 in the trench 220 is, for example, a chemical dry etching (CDE) process.

Next, referring to FIG. 2C, partial of the spacers 206 and partial of the block layer 208 are removed above the trench 220, so as to increase the width of the opening of the trench 220, and to help improving the trench filling capability when the conductor layer is filled in the trench 220. The method of removing partial of the spacers 206 and partial of the block layer 208 is, for example, a wet etching method, and a used etchant includes hydrogen fluoride and ethylene glycol. A concentration weight ratio value of ethylene glycol and hydrogen fluoride is, for example, 1-24.

Next, referring to FIG. 2D, the spacers 206, the block layer 208, and partial of the isolation structures 204 above the trench 220 are removed by, for example, a chemical mechanical polishing (CMP) process or the wet etching method, and a transistor 222 is formed in the trench 220. A gate structure 223 of the transistor 222 protrudes from the surface of the substrate 200. When the transistor 222 is formed, other passing gate structures 224 can be formed on the isolation structures 204. The methods of forming the transistor 222 and the passing gate structures 224 are well known by those of ordinary skill in the technical field, so they are not described here.

Next, a dielectric layer 226 covering the transistor 222 and the passing gate structures 224 is formed on the substrate 200. Then, a contact 228 electrically connected to a doped region 230 of the transistor 222 is formed in the dielectric layer 226. The materials of the transistor 222, the passing gate structures 224, the dielectric layer 226, and the contact 228 and the forming methods thereof are well known by those of ordinary skill in the technical field, so they are not described here.

It is known from the above that after the trench 220 is formed, the spacers 206 and the block layer 208 above the trench 220 are removed to enlarge the opening width of the trench 220. Therefore, when the gate structure 223 of the transistor 222 is formed in the trench 220, the trench filling capability of the conductor material filled into the trench 220 can be increased, such that voids will not be generated in the formed gate structure 223, thereby improving the electrical performance of the transistor 222.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a dynamic random access memory (DRAM), comprising:
providing a substrate having two trench capacitors therein, wherein an isolation structure is formed on top of each trench capacitor,
forming a spacer on top of the substrate and on a sidewall of each isolation structure;
forming a recessed area in the substrate and between the two trench capacitors;
enlarging the recessed area to form a trench in the substrate;
removing the spacers and a portion of the isolation structure; and
forming a gate structure in the trench.

2. The method for fabricating a DRAM as claimed in claim. 1, wherein the material of the isolation structures comprises silicon oxide.

3. The method for fabricating a DRAM as claimed in claim 1, wherein material of the spacers comprises silicon oxide.

4. The method for fabricating a DRAM as claimed in claim 1, wherein the recessed area forming step comprises an anisotropic etching.

5. The method for fabricating a DRAM as claimed in claim 4, wherein the anisotropic etching process comprises a reactive ion etching process.

6. The method for fabricating a DRAM as claimed in claim 5, wherein the recessed area enlarging step comprises an isotropic etching.

7. The method for fabricating a DRAM as claimed in claim 6, wherein the isotropic etching process comprises a chemical dry etching (CDE) process.

8. The method for fabricating a DRAM as claimed in claim 7, wherein the spacers and the portion of isolation structure removing step comprises a chemical mechanical polishing method.

9. A method for forming a trench in a substrate comprising:
forming at least two trench capacitors in the substrate, wherein an isolation structure is disposed on top of each of the two trench capacitors;
forming a spacer on a sidewall of the isolation structure to partially cover the substrate;
partially removing the substrate to form a recessed region;
enlarging the recessed region; and
removing the spacer and a portion of the isolation structure from the substrate.

10. The method as claimed in claim 9, wherein the substrate removing step comprises performing an anisotropic etching in the substrate by using the spacer and the isolation structure as hard masks.

11. The method as claimed in claim 10, wherein the recessed region enlarging step comprises performing a chemical dry etching to enlarge the recessed region.
